(19) United States
(12) Patent Application Publication
(10) Pub. No.: US 2001/0003300 A1
(43) Pub. Date: Jun. 14, 2001

(54) Non-contact radiating structure and radiating method

(76) Inventors: Shiro Soma, Tokyo (JP); Misao Iwatare, Tokyo (JP); Ou Matsumoto, Tokyo (JP); Masashi Takano, Tokyo (JP)

Correspondence Address: Whitham, Curtis & Whitham, Reston International Center, 11800 Sunrise Valley Dr., Suite 900, Reston, VA, 20191, US

(21) Appl. No.: 09/729,246

(22) Filed: Dec. 5, 2000

(30) Foreign Application Priority Data
Dec. 10, 1999 (JP) 352442/1999

(51) Int. Cl. F28F 7/00; F28D 15/00; H05K 7/20

(52) U.S. Cl. 165/41; 165/80.3; 165/104.33; 361/700

(57) ABSTRACT

There is disclosed a non-contact radiating structure provided with a plurality of space portions formed by a boundary wall. In the space portion a heating source and a heat pipe are installed in the vicinity of each other. Since the heating source and heat pipe in the same space portion are prevented by the boundary wall from being influenced by another heating source, each heat pipe efficiently transmits heat generated by the heating source. The radiating structure is installed in a housing installed outdoors. The heat pipe reaches the housing, and the heat is radiated to outside air from a housing outer surface.

### BACKGROUND OF THE INVENTION

1. Field of the Invention

The present invention relates to a non-contact radiating structure for performing heat radiation in a non-contact manner with a heating source and a radiating method.

2. Description of Related Art

One typical example of a non-contact radiating method with respect to a heating section of an electronic apparatus is a forced air cooling system by a fan. This system is applied to an electronic apparatus installed indoors in such a manner that management is constantly possible. However, in various electronic apparatuses installed outdoors, there is an apparatus in which it is difficult to constantly perform management. To cool this electronic apparatus, a cooling structure is required in which a fan or another movable portion is not disposed and maintenance is unnecessary. It is possible to naturally cool the electronic apparatus installed outdoors. Therefore, a radiating structure is proposed in which heat generated from the heating section in the electronic apparatus is conducted to an electronic apparatus housing to radiate the heat. For example, a heat pipe extended to the electronic apparatus housing from the heating section transmits heat to a heat sink on the surface of the housing or outside the housing in the structure. However, when the electronic apparatus is provided with a plurality of heating sections, and in the vicinity of the heating section another heating section is disposed, insufficient radiation occurs. Particularly, the heating section disposed in a middle portion of the electronic apparatus fails to sufficiently perform the radiation. Moreover, inside the electronic apparatus, the heat generated from a plurality of heating sections is gathered in the middle portion and upper portion of the apparatus. Therefore, the radiation is performed mainly by the heat pipe disposed in these areas. On the other hand, the heat pipe disposed in the lower portion of the apparatus and in a peripheral area in the apparatus fails to be effectively utilized. Specifically, all the heat pipes installed for radiation in the apparatus fail to be sufficiently utilized.

### SUMMARY OF THE INVENTION

Therefore, an object of the present invention is to provide a non-contact radiating structure and a radiating method for efficiently radiating heat generated in an electronic apparatus.

To achieve the aforementioned object according to the present invention there is provided a non-contact radiating structure comprising: a heat pipe for conducting heat; and a space portion for containing the heat pipe and a heating source. The heating source is installed in the vicinity of the heat pipe in the space portion. In the radiating structure, a plurality of space portions are formed to be adjacent to one another via boundary walls. For the plurality of space portions a common heat pipe is disposed. One space portion can contain one heating source and one heat pipe. Moreover, at least one of the heating source and the heat pipe in one space portion can be plural. Furthermore, according to the present invention there is provided a non-contact radiating method comprising steps of: disposing a heating source and a heat pipe in the vicinity of each other; covering the heating source and the heat pipe with a boundary wall; and transmitting heat generated from the heating source to the heat pipe.

In the aforementioned non-contact radiating structure and radiating method, the heating source in the space portion fails to be influenced by the heat of the heating source installed in another space portion. Most part of the heat generated from the heating source is conducted and radiated through the heat pipe installed in the same space. Therefore, the respective heat pipes are utilized in a substantially equal manner, and the heat generated by the heating source is efficiently radiated.

### BRIEF DESCRIPTION OF THE DRAWINGS

The above and other objects, features and advantages of the present invention will become apparent from the following detailed description when taken with the accompanying drawings in which:

FIG. 1 is a sectional view showing an embodiment of a non-contact radiating structure;

FIG. 2A and FIG. 2B are sectional views of one space portion; and

FIG. 3 is a sectional view showing another embodiment of the non-contact radiating structure.

### DETAILED DESCRIPTION OF THE PREFERRED EMBODIMENTS

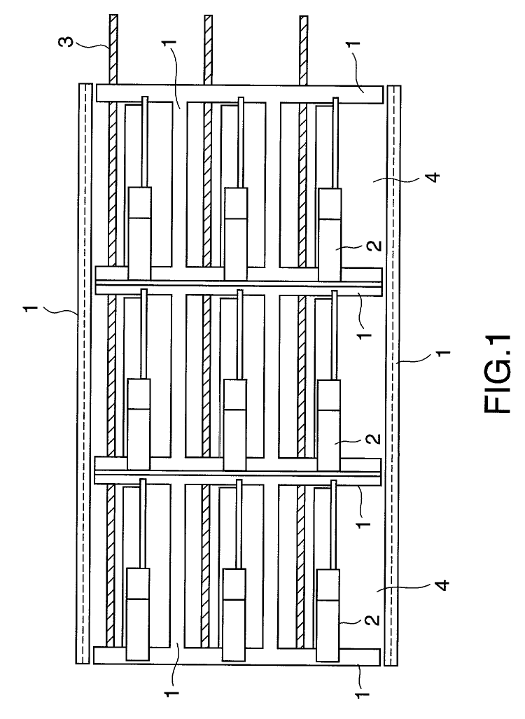

Referring to FIG. 1, in a non-contact radiating structure of the present invention, an aluminum boundary wall 1 is assembled in a grating shape to form a plurality of space portions 4. A common heat pipe 3 is also disposed in at least one adjacent space portion 4. This radiating structure is installed in a housing (not shown), and the housing is installed outdoors. Moreover, at least one end of the heat pipe 3 reaches the housing which contains the radiating structure. In the space portion 4, in addition to one heat pipe 3, one heating source 2 is installed. The heat pipe 3 is disposed in the vicinity of the heating source 2 in such a manner that heat is transmitted as efficiently as possible. The heating source 2 is an electronic circuit formed on a substrate or in a substrate, and is provided, for example, with a size of 100 mm×60 mm× 30 mm. A part of the substrate is attached to the boundary wall 1. The plurality of space portions 4 are each of a rectangular parallelepiped shape, but a cylindrical shape, a honeycomb shape, or another shape can be used. The heat pipe 3 disposed in one space portion 4 can directly reach the housing, not via another space portion 4. Moreover, for the space portion 4, peripheries of the heating source 2 and heat pipe 3 may all be covered with the boundary wall 1 in the structure, or an opening may be formed on a specified side in order to install the substrate with the electronic circuit formed thereon. In the non-contact radiating structure, the heating source 2 is prevented by the boundary wall 1 from being influenced by the heat from another heating source 2. Therefore, the heat pipe 3 can efficiently transmit and radiate the heat of the heating source 2 (electronic circuit) to the housing. Moreover, since the boundary wall 1 itself is formed of a metal, the heat can be transmitted to the outside of the radiating structure.

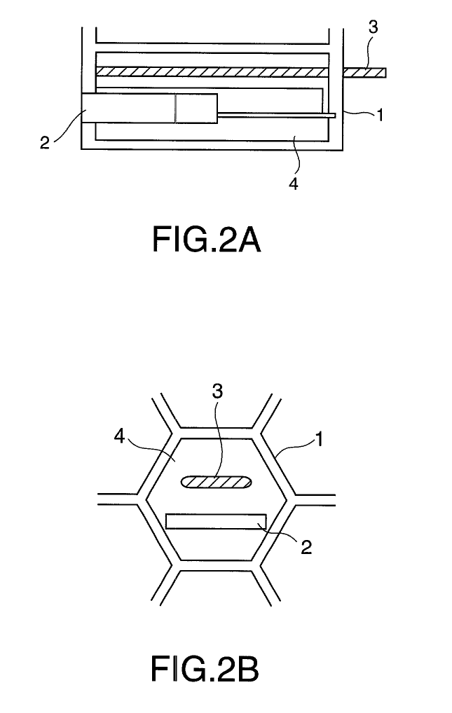

Referring to FIG. 2A, FIG. 2B, one space portion 4 can be of the rectangular parallelepiped shape (FIG. 2A), or the honeycomb shape (FIG. 2B). The heat pipe 3 can be of a columnar shape, a flat plate shape, or another shape, but is preferably installed above the heating source 2 (electronic circuit). Moreover, the heat pipe can also be installed above and below the heating source 2 in the structure. When heat is generated mainly from a specified part of the electronic circuit on the substrate, the heat pipe 3 is disposed in the vicinity of the specified part. Since the surface of the heat pipe 3 expands a heat absorption area and enhances a heat absorption effect, a concave/convex portion can be formed. Moreover, the surface of the heat pipe 3 can be formed in black.

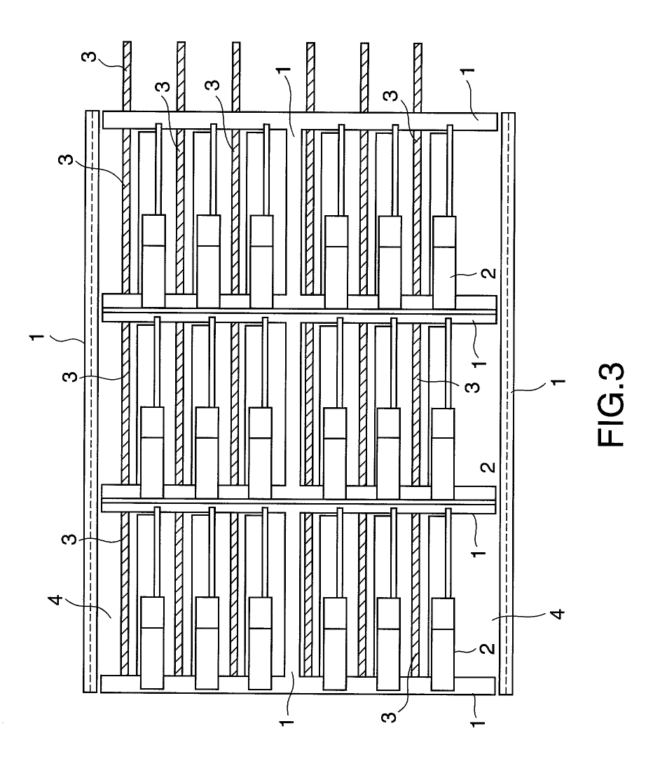

Referring to FIG. 3, three heating sources 2 and three heat pipes 3 are disposed in one space portion 4. When a quantity of heat generated from the heating source 2 is little, a plurality of heating sources 2 can be disposed in one space portion 4. Moreover, the number of heating sources 2 does not need to be the same as the number of heat pipes 3 in the same space portion 4.

In the non-contact radiating structure and radiating method of the present invention, since one or several heating sources 2 together with the heat pipe 3 are disposed in the vicinity of the space portion 4 formed by the boundary wall 1, the heat generated from the heating source 2 can efficiently be radiated using the heat pipe 3.

While the present invention has been described in connection with certain preferred embodiments, it is to be understood that the subject matter encompassed by the present invention is not limited to those specific embodiments. On the contrary, it is intended to include all alternatives, modifications, and equivalents as can be included within the spirit and scope of the following claims.

What is claimed is:

1. A non-contact radiating structure comprising:
a heat pipe for conducting heat; and
a space portion for containing said heat pipe and a heating source.

2. The non-contact radiating structure according to claim 1 wherein a plurality of space portions are formed to be adjacent to one another via boundary walls.

3. The non-contact radiating structure according to claim 1 wherein the heating source is installed in the vicinity of the heat pipe in said space portion.

4. The non-contact radiating structure according to claim 2 wherein for the plurality of space portions a common heat pipe is disposed.

5. The non-contact radiating structure according to claim 2 wherein a plurality of space portions form a honeycomb-shaped structure.

6. The non-contact radiating structure according to claim 1 wherein one space portion contains one heating source and one heat pipe.

7. The non-contact radiating structure according to claim 1 wherein a plurality of either heating sources or heat pipes are contained in one space portion.

8. The non-contact radiating structure according to claim 2 wherein the space portion is closed by the boundary wall.

9. The non-contact radiating structure according to claim 2 wherein the space portion formed by the boundary wall is provided with an opening.

10. The non-contact radiating structure according to claim 1 wherein the heating source is an electronic circuit formed on a substrate.

11. The non-contact radiating structure according to claim 1 wherein the radiating structure is contained in a housing, and
at least one end of the heat pipe contacts the housing.

12. The non-contact radiating structure according to claim 11 wherein the housing is installed outdoors.

13. The non-contact radiating structure according to claim 1 wherein the radiating structure is formed using a metal material.

14. A non-contact radiating method comprising steps of:
disposing a heating source and a heat pipe in the vicinity of each other;
covering the heating source and the heat pipe with a boundary wall; and
transmitting heat generated from the heating source to the heat pipe.

15. The non-contact radiating method according to claim 14, further comprising a step of covering one heating source and one heat pipe with the boundary wall.

16. The non-contact radiating method according to claim 14 wherein at least one of the heating source and the heat pipe covered with the boundary wall is plural.
